(19) United States
(12) Patent Application Publication
(10) Pub. No.: US 2014/0230721 A1
(43) Pub. Date: Aug. 21, 2014

(54) APPARATUS FOR FABRICATING INGOT, METHOD FOR PROVIDING MATERIAL, AND METHOD FOR FABRICATING INGOT

(71) Applicants: Ji Hye Kim, Seoul (KR); Kyoung Seok Min, Seoul (KR); Dong Geun Shin, Seoul (KR)

(72) Inventors: Ji Hye Kim, Seoul (KR); Kyoung Seok Min, Seoul (KR); Dong Geun Shin, Seoul (KR)

(73) Assignee: LG INNOTEK CO., LTD., Seoul (KR)

(21) Appl. No.: 14/241,016

(22) PCT Filed: Aug. 16, 2012
(86) PCT No.: PCT/KR2012/006515

§ 371 Date: Apr. 30, 2014

(30) Foreign Application Priority Data
Aug. 25, 2011 (KR) 10-2011-0085289

(51) Int. Cl. C30B 23/02

(52) U.S. Cl. CPC C30B 23/02
USPC 117/84; 118/726

(57) ABSTRACT

An apparatus for fabricating an ingot according to the embodiment comprises a crucible for receiving a raw material, wherein the raw material comprises first powder and second powders having grain sizes different from each other. A method for providing a raw material according to the embodiment comprises preparing a crucible including a central area and an edge area which surrounds the central area; filling a first powder in the central area; and filling a second powder in the edge area, the second powder having a grain size different from a grain size of the first powder.

### TECHNICAL FIELD

The disclosure relates to an apparatus for fabricating an ingot, a method for providing a material and a method for fabricating an ingot.

### BACKGROUND ART

SiC represents the superior thermal stability and superior oxidation-resistance property. In addition, the SiC has the superior thermal conductivity of about 4.6 W/Cm° C., so the SiC can be used for fabricating a large-size substrate having a diameter of about 2 inches or above. In particular, the single crystal growth technology for the SiC is very stable actually, so the SiC has been extensively used in the industrial field as a material for a substrate.

In order to grow the single crystal for SiC by using a seed, a seeded growth sublimation scheme has been suggested. In this case, after putting SiC powder serving as a raw material in a crucible, a SiC single crystal serving as a seed is provided over the raw material. In addition, the temperature gradient is formed between the raw material and the seed, so that the raw material in the crucible is diffused toward the seed and re-crystallized to grow a single crystal.

When growing the single crystal, a temperature gradient is formed in a horizontal region of the raw material. The temperature gradient is varied depending on the distance from a crucible. Thus, a sublimation amount of the raw material varies. The single crystal has a convex shape due to the temperature gradient, and defects may occur in the single crystal.

### DISCLOSURE OF INVENTION

### Technical Problem

The embodiment can grow a high-quality single crystal.

### Solution to Problem

An apparatus for fabricating an ingot according to the embodiment comprises a crucible for receiving a raw material, wherein the raw material comprises first powder and second powders having grain sizes different from each other.

A method for providing a raw material according to the embodiment comprises preparing a crucible including a central area and an edge area which surrounds the central area; filling a first powder in the central area; and filling a second powder in the edge area, the second powder having a grain size different from a grain size of the first powder.

### Advantageous Effects of Invention

The apparatus for fabricating the ingot according to the embodiment comprises the first and second powders having grain sizes different from each other. The first and second powders may have the sublimation amounts which are different from each other, and may be placed according to the temperature gradient in the crucible. That is, the first powder having a small grain size may be placed in a high-temperature region of the crucible, and the second powder having a grain size larger than that of the first powder may be placed in a low-temperature region of the crucible. Thus, sublimation may be actively induced in the low-temperature region in the crucible and sublimation may be slowly induced in the high-temperature region in the crucible, so that uniform sublimation may occur. That is, the raw materials placed in a central area and an edge area of the crucible may be uniformly sublimated. Thus, the central area of the fabricated single crystal may be prevented from being configured as a convex shape. Therefore, a high-quality single crystal may be obtained and a product yield of the wafers fabricated from the single crystal may be improved.

Further, due to carbonization distribution according to the uniform sublimation of the raw material, consumption efficiency of the raw material can be improved. Thus, the manufacturing cost may be reduced.

According to the method for providing the raw material of the embodiment, the raw material having the above-described effects can be provided.

### BRIEF DESCRIPTION OF DRAWINGS

FIG. 1 is a sectional view of an apparatus for fabricating an ingot according to the first embodiment;

FIG. 2 is a plan view of the apparatus for fabricating the ingot according to the first embodiment;

FIG. 3 is a sectional view of an apparatus for fabricating an ingot according to the second embodiment;

FIG. 4 is a plan view of the apparatus for fabricating the ingot according to the second embodiment;

FIG. 5 is a flowchart showing a method for fabricating an ingot according to the first embodiment; and

FIG. 6 is a flowchart showing a method for fabricating an ingot according to the second embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or over the other substrate, layer (or film), region, pad, or pattern, or one or more intervening layers may also be present. Such a position of the layer has been described with reference to the drawings.

Since the thickness and size of each layer shown in the drawings may be modified for the purpose of convenience or clarity of description, the size of elements does not utterly reflect an actual size.

Hereinafter, the embodiments will be described with reference to accompanying drawings.

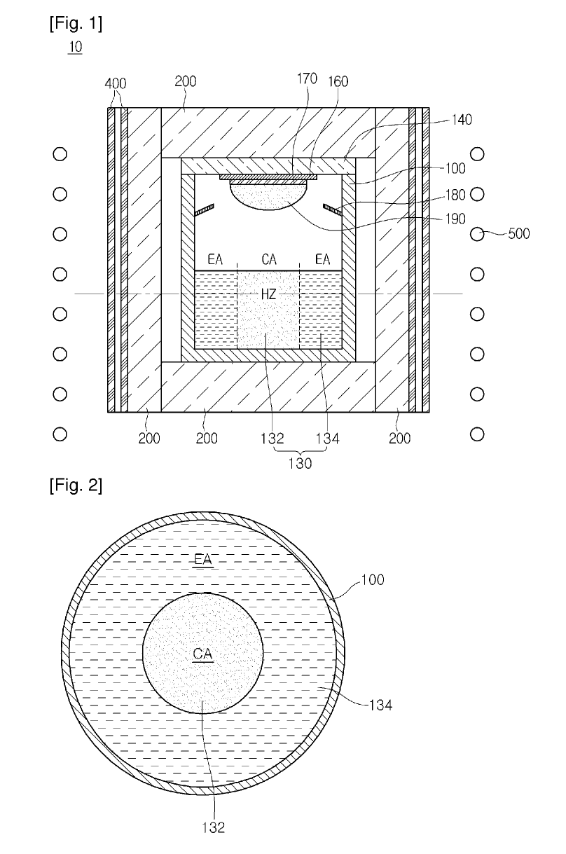

An apparatus for fabricating an ingot according to the first embodiment will be described in detail with reference to FIGS. 1 and 2. FIG. 1 is a sectional view of the apparatus for fabricating the ingot according to the first embodiment. FIG. 2 is a plan view of the apparatus for fabricating the ingot the first embodiment.

Referring to FIGS. 1 and 2, the apparatus 10 for fabricating the ingot according to the first embodiment comprises a crucible 100, a raw material 130, an upper cover 140, a seed holder 160, a focusing tube 180, a thermal insulator 200, a quartz tube 400, and a heat generation induction part 500.

The crucible 100 may receive the raw material 130 therein.

The crucible 100 may have a cylindrical shape such that the crucible 100 can receive the raw material 130.

The crucible 100 may comprise a material having a melting point equal to or higher than the sublimation temperature of silicon carbide.

For example, the crucible 100 may be formed by using graphite.

Further, a material having a melting point equal to or higher than the sublimation temperature of silicon carbide may be coated on the graphite of the crucible 100. A material chemically inactive with respect to silicon and hydrogen at the temperature at which silicon carbide single crystal 190 is grown is preferably used as the material coated on the graphite. For example, metal carbide or metal nitride may be used. Specifically, a mixture including at least two of Ta, Hf, Nb, Zr, W and V and carbide including carbon may be coated. Further, a mixture including at least two of Ta, Hf, Nb, Zr, W and V and nitride including nitrogen may be coated.

The raw material 130 may comprise silicon and carbon. In more detail, the raw material 130 may be a compound including silicon, carbon, oxygen and hydrogen. The raw material 180 may be silicon carbide (SiC) powder

The raw material 130 may comprise the first and second powders 132 and 134 having grain sizes different from each other.

The first powder 132 and the second powder 134 may be filled at different ratios. For example, the first powder 132 and the second powder 134 may be filled at the ratio of 1:2.

The grain size of the first powder 132 may be smaller than that of the second powder 134. The first and second powders 132 and 134 may be granule powders. In detail, the grain size of the first powder 132 may be in the range of 20 μm to 30 μm, and the grain size of the second powder 134 may be in the range of 200 μm to 300 μm.

The first and second powders 132 and 134 may be placed at different positions in the crucible 100. The first and second powders 132 and 134 may be disposed according to temperature distribution in the crucible 100.

The crucible 100 may generate heat by itself using the heat generation induction part 500, so that a temperature gradient is formed in the crucible 100. In detail, the crucible 100 comprises a central area CA and an edge area EA which surrounds the central area CA, and the edge area EA, which is closed to the crucible 100, has a high-temperature region. However, a portion which is relatively remote from the crucible 100, that is, the central area CA has a low-temperature region.

The firs powder 132 may be placed at the low-temperature region in the crucible 100. That is, the first powder 132 may be placed at the central area CA. Further, the second powder 134, which has the grain size greater than that of the first powder 132, may be placed at the high-temperature region in the crucible 100. That is, the second powder 134 may be placed at the edge area EA.

Since the grain size of the first powder 132 is small, the first powder 132 has great surface energy, so that sublimation may occur actively at the ingot growth temperature.

Since the grain size of the second powder 134 is larger than that of the first powder 132, the surface energy of the second powder 134 is low, so that the sublimation rate may be low at the ingot growth temperature.

The sublimation may be actively induced by placing the first powder 132 at the central area CA which corresponds to the low-temperature region in the crucible 100.

Further, the sublimation may be slowly induced by placing the second powder 134 at the edge area EA which corresponds to the high-temperature region in the crucible 100.

Thus, the sublimation may occur entirely and uniformly. That is, the raw material 130 may be sublimated uniformly at the central and edge areas CA and EA, so that the fabricated single crystal may be prevented from being configured as the convex shape. Therefore, a high-quality single crystal may be obtained and the product yield of the wafers fabricated from the single crystal may be improved.

Because of carbonization distribution according to the uniform sublimation of the raw material, the consumption efficiency of the raw material may be improved. Thus, the fabrication cost may be reduced.

In the related art, since a uniform raw material is filled in the crucible 100, the sublimation behavior of the raw material may vary depending on the temperature gradient in the crucible 100. Accordingly, there is great variation of sublimation degree on the surface of the raw material. That is, the sublimation degree is great at the surface of the raw material placed on the edge area EA, and the sublimation may not be effectively carried out at the surface of the raw material placed at the central area CA. This temperature gradient is increased as time elapses. That is, since the raw material placed at the edge area EA is more sublimated, the temperature of the edge area EA is more increased due to graphitization of the raw material placed at the edge area EA. Further, sintering of the raw material may occur at the central area CA and the center of an upper portion of the crucible 100 in which the sublimation amounts are small, so that the raw material may be inefficiently consumed. Further, the single crystal may grow in the convex shape due to the variation in the temperature gradient and the sublimation degree, and the product yield of the wafers fabricated from the single crystal may be reduced.

Then, the upper cover 140 may be placed at an upper portion of the crucible 100. The upper cover 140 may seal the crucible 100. The upper cover 140 may seal the crucible 100, such that reaction can occur in the crucible 100.

The upper cover 140 may comprise graphite. However, the embodiment is not limited thereto, and the upper cover 140 may comprise a material having a melting point which is equal to or higher than the sublimation temperature of silicon carbide.

The seed holder 160 is placed at the lower end portion of the upper cover 140. That is, the seed holder 160 is disposed over the raw material 130.

The seed holder 160 may fix the seed 170. The seed holder 160 may comprise high-density graphite.

The focusing tube 180 is placed in the crucible 100. The focusing tube 180 may be placed at a portion on which the single crystal is grown. The focusing tube 180 narrows a transfer passage of a sublimated silicon carbide gas, such that diffusion of the sublimated silicon carbide is concentrated on the seed 170. Thus, a growth rate of the single crystal may be increased.

The thermal insulator 200 surrounds the crucible 100. The thermal insulator 200 maintains the temperature of the crucible 100 at the crystal growth temperature. Since the crystal growth temperature of silicon carbide is very high, graphite felt may be used for the thermal insulator 200. In detail, the graphite felt used for the thermal insulator 200 may be manufactured in a cylindrical shape at a predetermined thickness by pressing a graphite fiber. Further, the thermal insulator 200 may be formed in a plurality of layers, so that the thermal insulator 200 may surround the crucible 100.

The quartz tube 400 is placed at a peripheral surface of the crucible 100. The quartz tube 400 is fitted around the peripheral surface of the crucible 100. The quartz tube 400 may prevent heat from transferring from the heat generation induction part 500 to the inside of the single crystal growth apparatus. The quartz tube 400 may be a hollow tube having an empty inner space. Cooling water may be circulated through the inner space of the quartz tube 400. Thus, the quartz tube 400 may more exactly control a growth rate and a growth size of the single crystal.

The heat generation induction part 500 is placed out of the crucible 100. For example, the heat generation induction part 500 may be a high-frequency induction coil. The crucible 100 may be heated as a high-frequency current flows through the high-frequency induction coil. That is, the raw material, which is received in the crucible 100, may be heated at the desired temperature.

The central area of the heat generation induction part 500, which is induction heated, is formed at a position lower than the central area of the crucible 100. Thus, the temperature gradient may be formed in the crucible 100 such that an upper portion and a low portion of the crucible 100 may have temperatures different from each other. That is, a hot zone (HZ), which is the center of the heat generation induction part 500, is located lower than the center of the crucible 100, so that the temperature of the low portion of the crucible 100 is higher than that of the upper portion of the crucible 100 about the hot zone (HZ). Further, the temperature becomes high from the central area to the outer peripheral portion of the crucible 100. Due to the temperature gradient, the silicon carbide raw material is sublimated and the sublimated silicon carbide gas moves to a surface of the seed 170 having the relatively low temperature. Thus, the silicon carbide gas is grown in a single crystalline structure 190 through the re-crystallization.

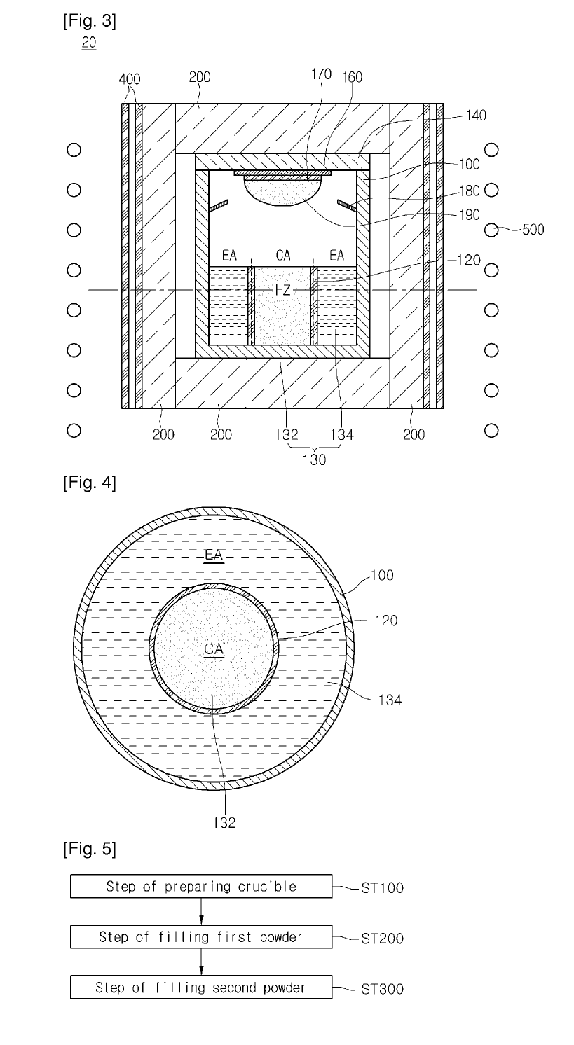

Hereinafter, an apparatus for fabricating an ingot according to the second embodiment will be described with reference to FIGS. 3 and 4. In the following description, for the purpose of clear and simple explanation, the details of structures and components the same as those in the first embodiment or similar to those in the first embodiment will be omitted.

FIG. 3 is a sectional view of the apparatus for fabricating the ingot according to the second embodiment. FIG. 4 is a plan view of the apparatus for fabricating the ingot according to the second embodiment.

Referring to FIGS. 3 and 4, the apparatus 20 for fabricating the ingot according to the second embodiment may further comprise a dividing part 120.

The dividing part 120 may be placed in the crucible 100. The dividing part 120 may be placed between the central area CA and the edge area EA of the crucible 100. That is, the dividing part 120 may divide the first powder 132 and the second powder 134 in the crucible 100 from each other. Thus, the first and second powders 132 and 134 having the different grain sizes may not be mixed with each other by the dividing part 120.

The dividing part 120 may comprise graphite.

Hereinafter, a method for providing a raw material according to the first embodiment will be described with reference to FIG. 5. FIG. 5 is a flowchart showing the method for providing the raw material according to the first embodiment

Referring to FIG. 5, the method for providing the raw material according to the first embodiment may comprise a step ST100 of preparing a crucible, a step ST200 of filling a first powder, and a step ST300 of filling a second powder.

In the step ST100 of preparing the crucible, the crucible filled with a raw material may be prepared. The crucible may comprise a central area and an edge area which surrounds the central area.

In the step ST200 of filling the first powder, the first powder may be filled in the central area. A grain size of the first powder may be smaller than that of the second powder. In detail, the grain size of the first powder may be in the range of 20 μm to 30 μm.

In the step ST300 of filling the second powder, the second powder may be filled in the edge area. The grain size of the second powder may be larger than that of the first powder. In detail, the grain size of the second powder may be in the range of 200 μm to 300 μm.

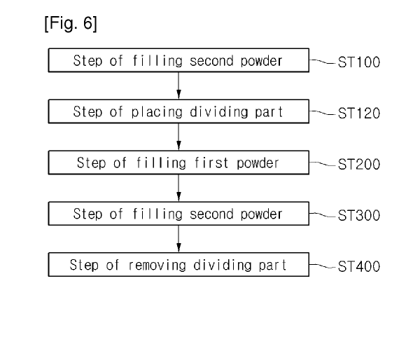

Hereinafter, a method for providing a raw material according to the second embodiment will be described with reference to FIG. 6. FIG. 6 is a flowchart showing the method for providing the raw material according to the second embodiment

Referring to FIG. 6, the method for providing the raw material according to the second embodiment may comprise a step ST100 of preparing a crucible, a step ST120 of placing a dividing part, a step ST200 of filling a first powder, a step ST300 of filling a second powder, and a step ST400 of removing the dividing part.

That is, the step ST120 of placing the dividing part may be further provided before the steps ST200 and ST300 of filling the first and second powders. The dividing part may be placed between the central area and the edge area. That is, the first and second powders having different grain sizes may be divided from each other.

The step ST400 of removing the dividing part may be provided after the steps ST200 and ST300 of filling the first and second powders. In the step ST400 of removing the dividing part, the dividing part placed in the crucible may be removed. Then, an ingot may be grown in the crucible.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for fabricating an ingot, the apparatus comprising:
a crucible for receiving a raw material, wherein the raw material comprises first and second powders having grains sizes different from each other.

2. The apparatus of claim 1, wherein the crucible comprises a central area and an edge area which surrounds the central area, and the grain size of the raw material filled in the central area is different from the grain size of the raw material filled in the edge area.

3. The apparatus of claim 2, wherein the grain size of the first powder is smaller than the grain size of the second powder.

4. The apparatus of claim 3, wherein the first powder is placed in the central area and the second powder is placed in the edge area.

5. The apparatus of claim 3, wherein the grain size of the first powder is in a range of 20 μm to 30 μm.

6. The apparatus of claim 3, wherein the grain size of the second powder is in a range of 200 μm to 300 μm.

7. The apparatus of claim 2, further comprising a dividing part placed between the central area and the edge area.

8. The apparatus of claim 7, wherein the dividing part comprises graphite.

9. A method for fabricating an ingot, the method comprising:
preparing a crucible including a central area and an edge area which surrounds the central area;
filling a first powder in the central area;
filling a second powder in the edge area, the second powder having a grain size different from a grain size of the first powder; and
growing an ingot from the first powder and the second powder.

10. The method of claim 9, wherein the grain size of the first powder is smaller than the grain size of the second powder.

11. The method of claim 9, further comprising:
placing a dividing part between the central area and the edge area before the filling of the first powder.

12. The method of claim 11, further comprising:
removing the dividing part before the growing of the ingot.
